(19) United States
(12) Patent Application Publication
(10) Pub. No.: US 2005/0277229 A1
(43) Pub. Date: Dec. 15, 2005

(54) Chip packaging structure and method of making wafer level packaging

(76) Inventors: Denny Chao, Tao Yuan Hsien (TW); Nico Lee, Hsinchu City (TW); Cyril Cheng, Hisnchu City (TW)

Correspondence Address: MORTON J. ROSENBERG;ROSENBERG, KLEIN & LEE, SUITE 101, 3458 ELLICOTT CENTER DRIVE, ELLICOTT CITY, MD, 21043, US

(21) Appl. No.: 11/209,827

(22) Filed: Aug. 24, 2005

Related U.S. Application Data
(63) Continuation of application No. 10/893,246, filed on Jul. 19, 2004.

(30) Foreign Application Priority Data
Mar. 26, 2004 (TW) 93108241

(51) Int. Cl. H01L 21/44

(52) U.S. Cl. 438/123

(57) ABSTRACT

The present invention provides a chip packaging structure and method of making wafer level packaging. Chip packaging structure comprises a chip, a dam formed surrounding the perimeter of the chip, and a frame glue coated over the surface of the dam. A transparent cover is formed on the top of the frame glue and adhered against the dam by the frame glue. A sealed space is formed between the transparent cover and the chip. The method of making wafer level packaging comprises the steps of: providing a wafer having a plurality of chip patterns thereon; forming a plurality of dams on the wafer and forming each dam surrounding each chip pattern; coating a frame glue over the surface of each dam; covering the transparent cover over the frame glue to form a plurality of sealed spaces between the transparent cover and the wafer, wherein each sealed space comprises a chip pattern; and dicing the chip patterns over the wafer as units in form a plurality of chip packaging structures. The present invention has highly reliability, high yield of luminous flux and photosensitive, simple manufacturing process and adhering frame glue uniformly.

### BACKGROUND OF INVENTION

1. Field of the Invention

The present invention relates to a chip packaging structure and method of making wafer level packaging, and more particularly to a chip packaging structure and method of making wafer level packaging having highly reliability, high yield of luminous flux and photosensitive.

2. Description of the Prior Art

Semiconductor technologies follow with rapid growing functions of computer and network communication products that essential to meet the requests of diversification, portable, light, thin and minimize. It makes chip packaging industrial away from traditional skills and developing towards high precision with high power, high density, light, thin and minimize, etc. Besides, electronics packaging more over needs high reliability and good cooling characters. Particularly, we must be more carefully with luminous flux, performance of photosensitive and reliability after finishing packaging of optical elements.

FIG. 1(a) shows a cross-sectional structure view of chip packaging structure of the prior art, and also refers to FIG. 1(b), which is the top view of the prior art. In the prior art, a chip packaging structure 10 has a chip 102 and the dam 104. The frame glue 106 are formed on the chip 102, wherein the frame glue 106 is coated around the dam and covered a glass 108 over the dam 104 and frame glue 106 to form a sealed space 110 between the glass 108 and the chip 102.

The wafer level packaging method of chip packaging structure 10 is shown in each step structure of cross-sectional view of FIG. 2(a) to FIG. 2(b). First of all, as FIG. 2(a) shown, a wafer 112 is provided, and a plurality of chip patterns are formed on the wafer 112; then as FIG. 2(b) shown, a dam 14 is formed on a glass 108 corresponding to the wafer 112; then as FIG. 2(c) shown, the frame glue is coated by rolling manner between the adjacent dam 104; and as FIG. 2(d) shown, a sealed space 110 is formed between glass 108 and wafer 112 by using aligners to align glass 108 and wafer 112 which have the dam 104 and the frame glue 106. Along with the scribe line to cut the dotted line as shown in FIG. 2(d), wherein each chip pattern as one unit, a plurality of chip packaging structures 10 are formed as shown in FIG. 1(a).

However, the wafer level packaging method of chip packaging structure 10 of the prior art has to utilize aligners to align the glass 108 and the wafer 112, and then it is able to press down while the glass 108 and the wafer 112 are aligned. During the pressing down process, it causes packaging structure easy to blow out due to air expansion by heating. Also by using the rolling manner to coat the frame glue 106 to form the frame glue 106 on the dam 104, it is hard to control the uniform surface of coating.

According to the disadvantage above, the present invention provides a chip packaging structure and method of making wafer level packaging having highly reliability, high yield of luminous flux and photosensitive in order to solve the above-mentioned problems.

### SUMMARY OF THE INVENTION

The primary object of the present invention is to provide a chip packaging structure and method of making wafer level packaging, which improve the disadvantages of prior art, that needs to align. The advantage of the manufacturing process more convenient is achieved.

Another object of the present invention is to provide a chip packaging structure and method of making wafer level packaging, wherein a transparent is covered over the frame glue under the condition of vacuum, filling the inert gas or in low air pressure environment. It renders chip packaging structure not easy to blow out. Therefore, it has higher reliability.

Another object of the present invention is to provide a chip packaging structure and method of making wafer level packaging under the condition of vacuum, filling inert gas or low air pressure environment. Due to the refractive index is “1” under vacuum condition, it has huge difference with the refractive index 1.5˜1.6 of lenticular on the chip pattern. It improves the focusing effect of the lenticular and increasing the yield of luminous flux, reliability, and photosensitive.

Another object of the present invention is to provide a chip packaging structure and method of making wafer level packaging, wherein a frame glue is coated over a dam by using the screen print manner for coating uniformly.

In accordance with the present invention, a chip packaging structure is provided, which comprises a chip, wherein a dam is formed surrounding the perimeter of the chip; a frame glue coated on the surface of the dam; a transparent cover covered over the top of the frame glue and adhered against the dam by the frame glue. A sealed space is formed between the transparent cover and the chip.

The present invention also provides the method of making wafer level packaging structure, comprising the steps of: providing a wafer, wherein a plurality of chip patterns are formed on the top of the wafer; forming a plurality of dams surrounding the perimeter of the chips, wherein each dam is formed surrounding each chip; coating the frame glue around the surface of the dams; covering a transparent cover over the frame glue to form a plurality of sealed spaces between the transparent cover and the wafer, wherein each sealed space comprises a chip pattern: and dicing the chip pattern on the wafer as units to form a plurality of chip packaging structures.

### BRIEF DESCRIPTION OF THE DRAWINGS

The object and other advantages of this invention are best described in the preferred embodiment, with reference to the attached drawings that include:

FIG. 1(a) shows a cross-sectional structure view of chip packaging structure according to the prior art.

FIG. 1(b) is the top view of FIG. 1(a) according to the prior art.

FIGS. 2(a) to (d) are the cross-sectional views showing the steps according to the prior art.

FIG. 3(a) is the cross-sectional view according to the present invention.

FIGS. 4(a) to (d) are the cross-sectional views showing the steps according to the present invention.

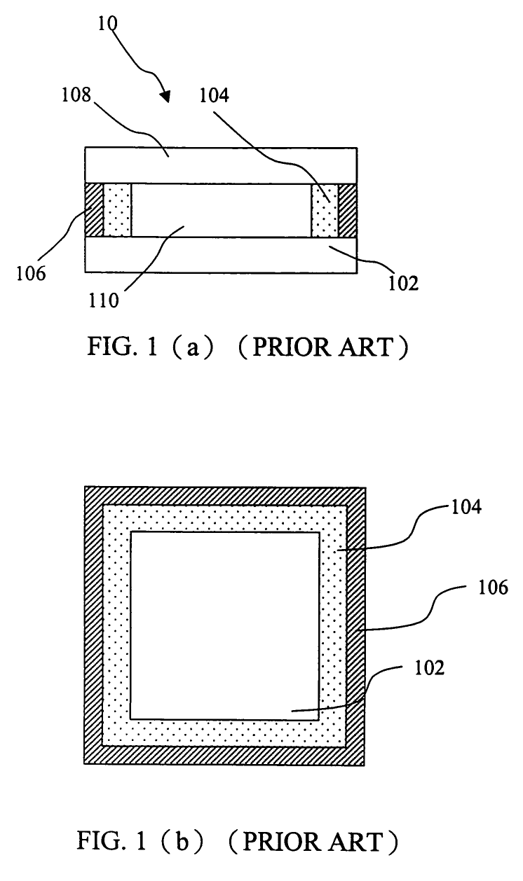

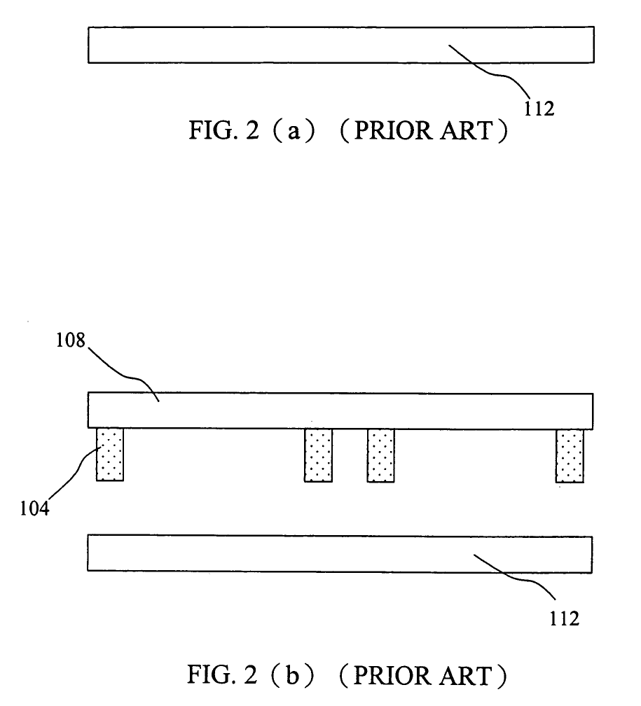

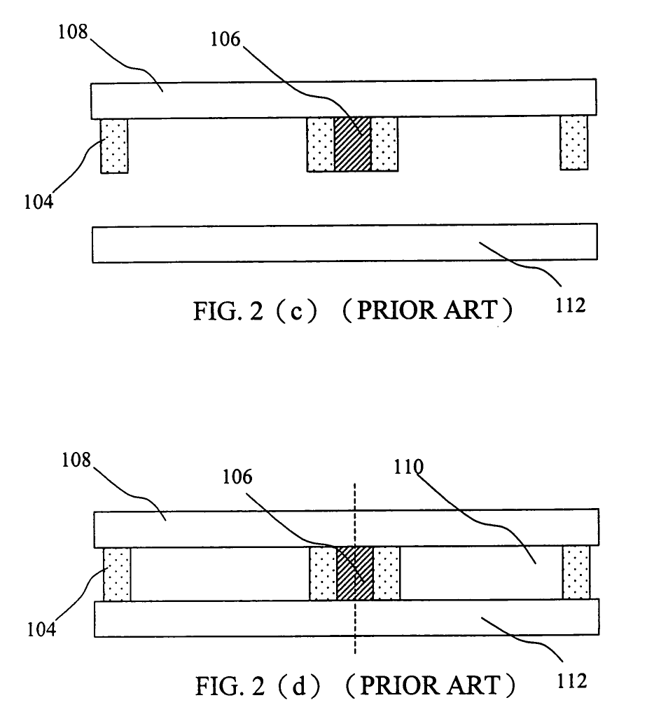

### DETAILED DESCRIPTION OF THE PREFERRED EMBODIMENTS

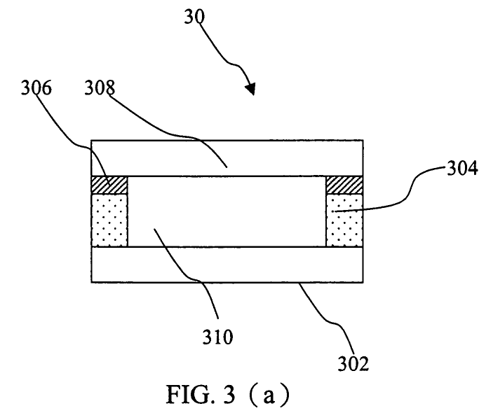

The cross-sectional view of the present invention as shown in FIG. 3(a), the chip packaging structure 30 comprises a chip 302, a dam 304 surrounding the perimeter of the chips 302, and a frame glue 302 coating on the surface of the dam 304. A transparent cover 308, such as the glass, is covered over the top of the frame glue 306 and adhered against the dam 304 by the frame glue 306. A sealed space 310 is formed between the transparent cover and the chip, wherein the sealed space 310 is in the condition of vacuum, filling the inert gas, such as nitrogen, or low gas pressure environment.

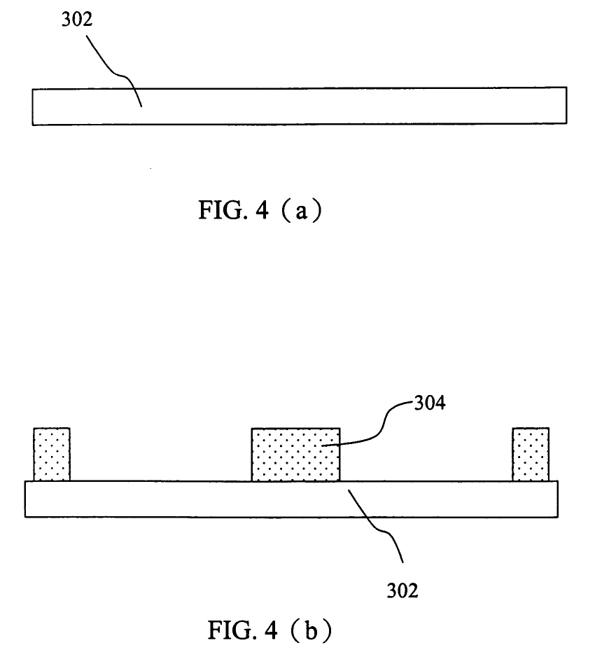

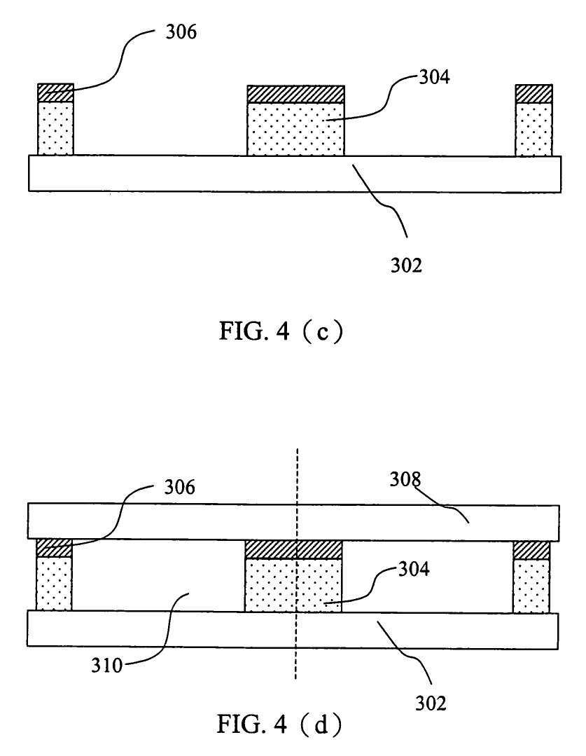

The present invention also provides a chip packaging structure and method of making wafer level packaging. As shown in FIGS. 4(a) to (d), there are the cross-sectional views showing the steps according to the present invention. First of all, as shown in FIG. 4(a), a wafer 312 is provided, wherein a plurality of chip patterns are formed on the top of the wafer 312. As shown in FIG. 4(b), dams 304 are formed surrounding the perimeter of the wafer 312, and each dam 304 is formed surrounding the perimeter of each chip pattern. As shown in FIG. 4(c), the frame glue 306 is coated over the surface of the dam 304. As shown in FIG. 4(d), in the vacuum environment, filling the inert gas or low pressure conditions environment, a transparent cover 308 is covered over the top of the frame glue 306 to form a sealed space between the transparent cover 308 and the wafer 312. Along the scribe line as the dotting line as shown in FIG. 4(d), a plurality of chip packaging structures 30 are formed by dicing the chip patterns as units as shown in FIG. 3(a).

Further, at the steps of covering a transparent cover 308 over the frame glue 306 in the vacuum environment, low pressure environment or filling the inert gas conditions, it renders the packaging structure will not blow out due to expand when heating. Also, because the refractive index under vacuum status is “1”, when the chip packaging structure 30 is used to an optical packaging element, the chip patterns dispose plural lenticule (not shown in the drawings), and the refractive index 1.5˜1.6 of lenticular on the chip pattern. It improves the focusing effect of the lenticular and increasing the yield of luminous flux, reliability, and photosensitive; moreover, the method of coating frame glue 306 utilizes screen print manner. It renders controlling the gluing volume, uniformity and accurate more efficiency.

The present invention provides a chip packaging structure and method of making wafer level packaging, wherein a transparent cover is covered over the frame glue in the vacuum environment, low pressure environment or filling the inert gas conditions. It renders the chip packaging structure not easy to blow out and more reliable, and there is no need to align position between the chip and the glass, to simplify the manufacturing process, By using the screen print manner to coat the frame glue over dams, it renders the coating more uniformly.

Thus, a chip packaging structure and method of making wafer level packaging has been described. Although the present invention has been described with reference to specific exemplary embodiments, it will be evident that various modifications and changes may be made to these embodiments without departing from the broader spirit and scope of the invention.

1-6. (canceled)

7. A method of making wafer level packaging, comprising the steps:
providing a wafer having a plurality of chip patterns thereon;
forming a plurality of dams on said wafer, wherein each dam is formed surrounding each chip pattern;
coating a frame flue over the surface of each dam;
covering a transparent cover over said frame glue to form a plurality of sealed spaces between said transparent cover and said wafer, wherein each sealed space comprises one said chip pattern; and dicing said chip patterns as units on said wafer to form a plurality of chip packaging structures.

8. The method of making wafer level packaging according to claim 7, wherein the step of covering said transparent cover over said frame glue is performed under the vacuum condition.

9. The method of making wafer level packaging according to claim 7, wherein the step of covering said transparent cover over said frame glue is performed under full of inert gas condition.

10. The method of making wafer level packaging according to claim 9, wherein said inert gas is nitrogen.

11. The method of making wafer level packaging according to claim 7, wherein the step of the step of covering said transparent cover over said frame glue is performed under low-pressure condition.

12. The method of making wafer level packaging according to claim 7, wherein the step of coating said frame glue is used by the manner of screen print.
